(19) United States
(12) Patent Application Publication
(10) Pub. No.: US 2022/0055957 A1
(43) Pub. Date: Feb. 24, 2022

(54) METHOD OF MAKING A CERAMIC MATRIX COMPOSITE THAT EXHIBITS CHEMICAL RESISTANCE

(71) Applicant: Rolls-Royce High Temperature Composites Inc., Cypress, CA (US)

(72) Inventors: Sungbo Shim, Irvine, CA (US); Richard Kidd, Rancho Palos Verdes, CA (US); Kelly Kranjc, Irvine, CA (US); Robert Shinavski, Mission Viejo, CA (US)

(73) Assignee: Rolls-Royce High Temperature Composites Inc., Cypress, CA (US)

(21) Appl. No.: 17/405,273

(22) Filed: Aug. 18, 2021

Related U.S. Application Data
(60) Provisional application No. 63/067,449, filed on Aug. 19, 2020.

(51) Int. Cl. C04B 41/89; C04B 35/565; C04B 41/00; C04B 41/87; C04B 41/45; C04B 41/50

(52) U.S. Cl. CPC C04B 41/89; C04B 35/565; C04B 41/009; C04B 41/87; C04B 41/457; C04B 2235/5244; C04B 41/5066; C04B 41/5059; C04B 41/4523; C04B 41/4529; C04B 41/5064; C04B 41/4584

(57) ABSTRACT

A method of making a ceramic matrix composite that exhibits chemical resistance has been developed. The method comprises depositing a compliant layer comprising boron nitride, silicon-doped boron nitride, and/or pyrolytic carbon on silicon carbide fibers, depositing a barrier layer having a high contact angle with molten silicon on the compliant layer, and depositing a wetting layer comprising silicon carbide, boron carbide, and/or pyrolytic carbon on the barrier layer. After depositing the wetting layer, a fiber preform comprising the silicon carbide fibers is infiltrated with a slurry. After slurry infiltration, the fiber preform is infiltrated with a melt comprising silicon, and then the melt is cooled, thereby forming a ceramic matrix composite.

### RELATED APPLICATION

The present patent document claims the benefit of priority under 35 U.S.C. 119(e) to U.S. Provisional Patent Application No. 63/067,449, which was filed on Aug. 19, 2020, and is hereby incorporated by reference in its entirety.

### TECHNICAL FIELD

The present disclosure relates generally to the fabrication of ceramic matrix composites (CMCs) and more particularly to fabricating a CMC which is resistant to chemical attack and environmental degradation while also exhibiting good mechanical properties.

### BACKGROUND

Ceramic matrix composites, which include ceramic fibers embedded in a ceramic matrix, exhibit a combination of properties that make them promising candidates for industrial applications, such as gas turbine engines, that demand excellent thermal and mechanical properties along with low weight. A ceramic matrix composite that includes a silicon carbide matrix reinforced with silicon carbide fibers may be referred to as a silicon carbide/silicon carbide composite or SiC/SiC composite. Fabrication of a SiC/SiC composite may include slurry and melt infiltration steps to densify a silicon carbide fiber preform. Prior to the infiltration steps, the fibers making up the silicon carbide preform may be coated with one or more materials to protect the fibers and/or improve the performance of the final densified composite.

### BRIEF DESCRIPTION OF THE DRAWINGS

The embodiments may be better understood with reference to the following drawing(s) and description. The components in the figures are not necessarily to scale. Moreover, in the figures, like-referenced numerals designate corresponding parts throughout the different views.

FIG. 1 is cross-sectional schematic, not to scale, of a silicon carbide fiber coated with multiple functional layers.

FIG. 2 is a flow chart showing exemplary steps of the method.

FIG. 3 is a high-resolution transmission electron microscopy (TEM) image providing a cross-sectional view of a portion of a silicon carbide fiber coated with functional layers; scale bar is 50 nm.

### DETAILED DESCRIPTION

A method of making a ceramic matrix composite (CMC) that may show improved resistance to chemical attack from molten silicon along with excellent environmental resistance and mechanical performance is described. The method includes controllably depositing a sequence of coatings or layers, each having a particular function, on silicon carbide fibers that serve as reinforcements in the final CMC. After the layers are applied, a fiber preform comprising the silicon carbide fibers may undergo slurry infiltration and then melt infiltration to form the final CMC.

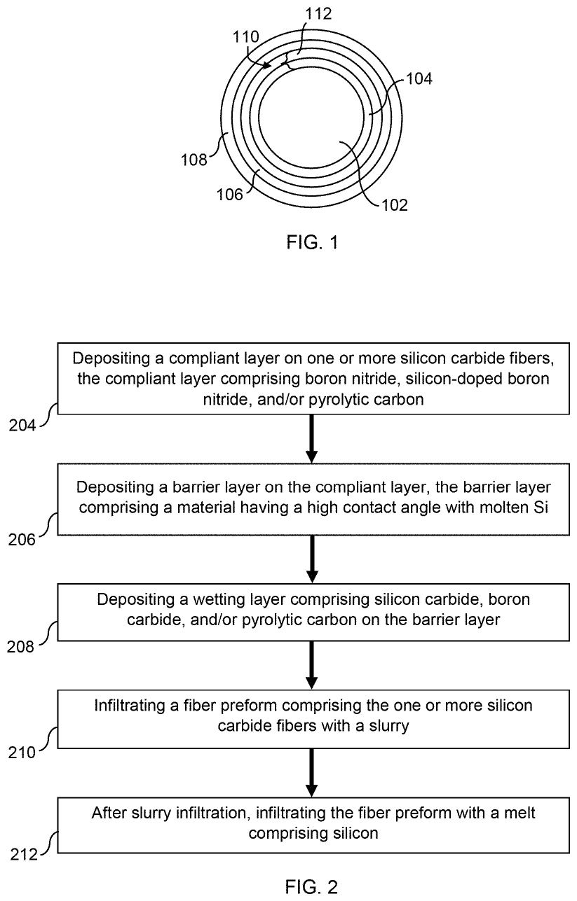

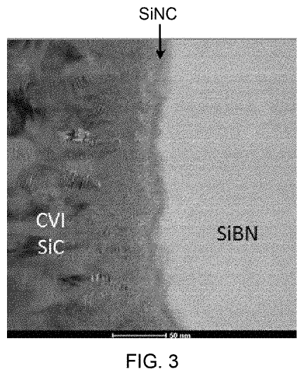

Referring to FIGS. 1 and 2, the method includes depositing 204 a compliant layer 104 comprising boron nitride, silicon-doped boron nitride, and/or pyrolytic carbon on one or more silicon carbide fibers 102, which may be referred to as “the silicon carbide fibers.” The compliant layer 104 may help to ensure a weak fiber-matrix interface in the finished CMC and promote matrix crack deflection, thereby improving fracture toughness. A barrier layer 106 comprising a material having a high contact angle with molten silicon is deposited 206 on the compliant layer 110. This barrier layer 106 may resist wetting by molten silicon and thus function as a chemical barrier against silicon attack during melt infiltration. In some examples, as discussed further below, the barrier layer 106 may have a sufficient thickness to serve as a rigidization layer. The compliant layer 110 may have a single-layer or multilayer structure, as shown in FIG. 1. A wetting layer 108 comprising silicon carbide, boron carbide (e.g., BₓC, where 0≤x≤4), and/or pyrolytic carbon is deposited 208 on the barrier layer 106. The wetting layer 108 may be readily wet by silicon and thus may promote formation of a porosity-free CMC during melt infiltration and cooling. In some examples, as discussed further below, the wetting layer may have a sufficient thickness to function as the rigidization layer. After depositing 208 the wetting layer 108, a fiber preform comprising the silicon carbide fibers is infiltrated 210 with a slurry, and, after slurry infiltration, the fiber preform is infiltrated 212 with a melt comprising silicon. Upon cooling of the melt, a dense CMC which includes the silicon carbide fibers in a ceramic matrix comprising silicon carbide may be formed.

The unique positioning of the barrier layer 106 between the compliant layer 104 and the wetting or rigidization layer 108 may lead to improvements in the fabrication and properties of the CMC. Previous work has shown that molten silicon can diffuse through a silicon carbide rigidization layer and chemically attack the underlying compliant layer and/or the silicon carbide fibers. In this disclosure, the barrier layer 106 is deposited prior to the rigidization or wetting layer 108 and thus is uniquely positioned to provide a chemical barrier against silicon attack without sacrificing the wettability desired for the wetting layer 108. Each of the layers, which may be referred to as “functional layers,” is described below in order of deposition.

First, it is noted that deposition of the functional layers on the silicon carbide fibers may be carried out using chemical vapor infiltration (CVI) methods. Generally speaking, CVI entails flowing gaseous reagents at an elevated temperature through a furnace or reaction chamber containing one or more porous specimens to be coated. The one or more porous specimens may comprise any arrangement of the silicon carbide fibers (e.g., a fiber preform and/or fiber tows, as discussed below), where interstices between adjacent silicon carbide fibers may be understood to constitute pores. During CVI, the gaseous reagents may infiltrate the porous specimen(s) (e.g., the fiber preform and/or the fiber tows) and chemically react to form a deposit, coating or layer on exposed surfaces of the silicon carbide fibers. The porous specimen(s) may be untooled or constrained with a tool during deposition. A suitable tool may include through-holes for passage of the gaseous reagents and may be formed of a chemically inert and/or refractory material, such as graphite or silicon carbide, which is stable at the elevated temperatures at which deposition takes place. Through-holes in the tool may have a diameter or width sized to allow for a sufficient flow of gaseous reactants into the porous specimen during CVI. The tool may have a single-piece or multi-piece construction suitable for constraining the porous specimen(s) in a desired configuration and for easy removal after deposition of the coatings.

As indicated above, the compliant layer 110 may comprise boron nitride, silicon-doped boron nitride, and/or pyrolytic carbon and may promote good fracture toughness in the finished CMC. Notably, the compliant layer 110 may have a sufficient thickness to prevent thermally-induced cracking of the barrier layer 106, which may have a coefficient of thermal expansion below that of the silicon carbide fibers. To deposit a compliant layer 110 comprising boron nitride (or, in the example of a compliant multilayer 110, an interface layer 104 comprising boron nitride as described below), the silicon carbide fibers 102 may be exposed to a gaseous atmosphere comprising a flow of nitrogen-containing gas, such as ammonia, and a flow of boron-containing gas, such as boron trichloride, at a temperature in a range from about 700° C. to about 875° C. The gaseous atmosphere may further comprise a flow of a substantially inert carrier gas such as N₂ or H₂. In one example, the compliant layer 110 may comprise a crystalline (hexagonal) phase of the boron nitride, which is preferred since amorphous or turbostratic boron nitride is more likely to degrade upon exposure to moisture and/or oxygen at elevated temperatures. Crystallinity of the boron nitride may be promoted or ensured by exposure to atmospheric humidity and a heat treatment as described below, which may optionally take place during CVI of a successive layer. To form pyrolytic carbon, which may refer to polycrystalline carbon or graphite formed in a pyrolytic process, the silicon carbide fibers 102 may be exposed to a gaseous atmosphere comprising a flow of a hydrocarbon-containing gas in the same or a similar temperature range.

If the compliant layer 110 comprises a boron nitride layer, it may be beneficial to further deposit on the boron nitride layer, prior to depositing the barrier layer 106, a moisture-tolerant layer 112 that comprises silicon-doped boron nitride. In such a case the compliant layer 110 has a multilayered structure including the moisture-tolerant layer 112 and the boron nitride layer, which may be referred to as an interface layer 104, as illustrated in FIG. 1. Silicon-doped boron nitride may more effectively resist environmental degradation and/or chemical attack from molten silicon than boron nitride. A concentration of silicon in the silicon-doped boron nitride may be in a range from about 2 at. % to about 30 at. %. To deposit either a compliant layer 110 or a moisture-tolerant layer 112 comprising silicon-doped boron nitride, a silicon-containing gas may be incorporated into the gaseous atmosphere in addition to the nitrogen-containing gas and the boron-containing gas. Suitable silicon-containing gases may include methyltrichlorosilane (CH₃SiCl₃), trichlorosilane (HSiCl₃), dichlorosilane (H₂SiCl₂), silicon tetrachloride (SiCl₄), and silane (SiH₄). Typically, CVI of silicon-doped boron nitride is carried out at a temperature in a range from about 700° C. to about 875° C. The gaseous atmosphere may further comprise a flow of a substantially inert carrier gas such as N₂ or H₂, where H₂ is preferred. It has been found that using H₂ as a carrier gas instead of N₂ may lead to a 50% increase in deposition rate of the silicon-doped boron nitride. Typically, deposition of the moisture-tolerant layer 112 may take place over a time duration of 10-70 hours. The moisture-tolerant layer 112 may have a thickness in a range from about 0.4 micron to about 3 microns. The interface layer 104 may have a thickness in a range from about 0.01 micron to about 0.10 micron and/or from 0.05 micron to about 0.1 micron, and deposition of the interface layer 104 may take place over a time duration of 1-10 hours.

In addition to serving as a compliant release layer, the interface layer 104 may function as a diffusion barrier between residual carbon (sizing) char on the silicon carbide fibers 102 and the moisture-tolerant layer 112. To promote crystallinity of the interface layer 104 (e.g., formation of the hexagonal boron nitride phase) as mentioned above, the method may further include exposing the interface layer 104 and/or the compliant layer 110 to atmospheric humidity, and then heat treating the interface layer 104 and/or the compliant layer 110 at a temperature in a range from about 900° C. to about 1150° C., preferably in an inert atmosphere.

The barrier layer 106 that overlies the single-layer or multilayer compliant layer 110 may have a high contact angle with molten silicon, such as a contact angle of at least about 45°, so as to serve as an effective chemical barrier. Accordingly, the barrier layer 106 may comprise silicon nitride or silicon nitrocarbide, such as SiₓN_{y}C_{z}, both of which may exhibit the requisite contact angle with molten silicon. In one example, 0.1<x<0.697, 0.3<y<0.6, and 0.003<z<0.33; that is, the barrier layer 106 may include carbon at a concentration from about 0.3 at. % to 33 at. % and nitrogen at a concentration from about 30 at. % to 60 at. %, with a balance of silicon and any incidental inpurities. Silicon nitrocarbide may be understood to comprise a mixture of silicon carbide (SiC), silicon nitride (Si₃N₄), and/or carbon (C). The silicon nitrocarbide may be amorphous and may remain amorphous during CVI processing due at least in part to the presence of carbon, which may inhibit or prevent crystallization. Consequently, crystallization-induced shrinkage cracking of the barrier layer 106, a problem that can be associated with amorphous silicon nitride, which does not include any appreciable amount of carbon, may be beneficially avoided. If the barrier layer 106 comprises silicon nitride (e.g., Si₃N₄), crystalline silicon nitride is preferred, and more particularly crystalline silicon nitride which is devoid of cracks. As indicated above, the crack resistance of the barrier layer 106 may be enhanced when the underlying compliant layer 110 has suitable thickness, such as from about 0.5 micron to about 3 microns. The barrier layer 106 may be deposited to have a thickness in a range from about 0.005 micron to about 2 micron, or more preferably in a range from about 0.5 micron to about 2 micron, when the barrier layer is intended to serve as a rigidization layer. In such a case, the wetting layer may be fairly thin, with a thickness in a range from about 0.01 micron to about 0.5 micron or more typically from about 0.01 micron to about 0.1 micron.

Deposition of the barrier layer 106 on the compliant layer 110 may comprise exposing the compliant layer 110 to a gaseous atmosphere comprising a flow of a silicon-containing gas and a flow of a nitrogen-containing gas, as described above, at a temperature in a range from about 700° C. to about 1000° C. The method may further include, when the compliant layer 110 comprises boron nitride or silicon-doped boron nitride, halting the flow of the boron-containing gas into the gaseous atmosphere, while the nitrogen- and/or silicon-containing gases continue to flow. It may be beneficial to halt the flow of the boron-containing gas for 5-30 minutes before the flows of the nitrogen- and silicon-containing gases are halted. If the intent is to deposit a barrier layer 106 comprising silicon nitrocarbide, instead of silicon nitride, then a flow of a carbon-containing gas may be included in the gaseous atmosphere. The carbon-containing gas may be the same as or different from the silicon-containing gas or the nitrogen-containing gas. In other words, the silicon-containing gas or the nitrogen-containing gas may also include carbon. One example of a silicon-containing gas that includes carbon is methyltrichlorosilane (CH₃SiCl₃), as mentioned above, which is also known as MTS. In addition to the silicon-, nitrogen- and/or carbon-containing gases, which may individually or collectively be referred to as reactive gas(es), the gaseous atmosphere may further include a flow of a carrier gas, which as indicated above may be a nonreactive gas that does not participate in the CVI reaction, and which may be selected from N₂ and H₂.

After deposition of the barrier layer 106, the wetting layer 108 may be deposited. Typically, the wetting layer 108 comprises silicon carbide, boron carbide, and/or pyrolytic carbon. Deposition may entail CVI utilizing a flow of a silicon-containing gas that further contains carbon, such as the MTS mentioned above. Prior to CVI of the wetting layer, the flow of all gases except the carrier gas (e.g., H₂ or N₂) may be halted and the furnace may be cooled. Typically, the wetting layer 108 has a thickness in a range from about 0.2 micron to about 2 microns, where higher thicknesses may be employed if the wetting layer 108 is intended to function as a rigidization layer. For example, if silicon carbide is selected for the wetting layer 108, and the thickness of the wetting layer 108 lies in a range from about 0.5 micron to about 10 microns, then the wetting layer 108 may be able to provide a rigidization function in addition to a wetting function. In such an example, the barrier layer 106 may be fairly thin, with a thickness in a range from about 0.005 micron to about 0.5 micron or more typically from about 0.005 micron to about 0.1 micron. CVI of the wetting layer 108 may be carried out from about 1 hour to about 60 hours, and generally at a temperature in a range from about 600° C. to about 1500° C.

The silicon carbide fibers 102 that undergo coating may be arranged in a fiber tow, unidimensional tape, braid, ply, and/or woven fabric (e.g., 2D woven, 3D woven and/or 2.5D woven), and may further be part of a fiber preform that has a predetermined shape, such as an airfoil shape. The fiber preform is typically produced in a lay-up process from the plies, woven fabrics and/or tapes and may be described as a three-dimensional framework of the silicon carbide fibers or fiber tows. Typically, the silicon carbide fibers are assembled into a fiber preform prior to CVI.

After deposition of the functional layers, the silicon carbide fibers may be referred to as coated silicon carbide fibers, and the fiber preform may be referred to as a rigidized preform. Deposition of the functional layers may be followed by slurry infiltration to impregnate the rigidized preform with matrix precursors, forming what may be referred to as an impregnated fiber preform. A suitable slurry may include ceramic (e.g., silicon carbide) particles and/or particulate reactive elements (e.g., elements reactive with molten silicon or a molten silicon alloy), such as carbon, in an aqueous or organic liquid. The slurry may further include a carbonaceous resin, such as phenolic or furfuryl alcohol. In some cases, the carbonaceous resin may be separately infiltrated into the rigidized preform after slurry infiltration, or may not be used at all. If a carbonaceous resin is employed, one or more additional steps, such as curing and/or pyrolysis, may be carried out to convert the resin to carbon. Typically, the impregnated fiber preform comprises a loading level of particulate matter, including ceramic particles and particulate reactive elements, from about 40 vol. % to about 60 vol. %, with the remainder being porosity. The method may further comprise infiltrating the fiber preform with molten material (e.g., molten silicon or a molten silicon alloy) followed by cooling to form a densified ceramic matrix composite. Due to the presence of the barrier coating, the silicon carbide fibers and the compliant layer (or interface multilayer) may be protected from attack by molten silicon.

During melt infiltration, the molten material infiltrated into the rigidized and/or impregnated fiber preform may consist essentially of silicon (e.g., elemental silicon and any incidental impurities) or may comprise a silicon-rich alloy. Melt infiltration may be carried out at a temperature at or above the melting temperature of silicon or the silicon alloy which is infiltrated. Thus, the temperature for melt infiltration is typically in a range from about 1380° C. to about 1700° C. In one example, a ramp rate from an intermediate temperature of about 800° C. to a temperature above about 1380° C. may be less than about 10° C./min. A suitable time duration for melt infiltration may be from 15 minutes to four hours, depending in part on the size and complexity of the ceramic matrix composite to be formed. A ceramic matrix is formed from ceramic particles as well as ceramic reaction products created from reactions between the molten material and any other particles (e.g., carbon particles, refractory metal particles) in the fiber preform. Preferably, the final ceramic matrix composite is substantially devoid of closed porosity. In some cases, the ceramic matrix composite may form part or all of a gas turbine engine component, such as a blade or vane.

### Example

5HS Hi-Nicalon Type S fabric is preformed into a 6.5″×7″×0.200″ panel, tooled into a graphite tool with diffusion holes, and loaded in a furnace. After evacuation, the furnace is heated to 1000° C. for 5 mins to 1 hour for heat treatment of the panel/fiber preform. The furnace temperature is then cooled to 750 to 850° C. and flows of N₂, BCl₃, and NH₃ are introduced for three hours to apply a compliant layer comprising boron nitride on the silicon nitride fibers of the preform. Next, a flow of MTS is added to the gaseous atmosphere for 25 to 40 hours, and a moisture tolerant layer comprising silicon-doped boron nitride is deposited on the compliant layer, forming an interface multilayer. In a next step, the BCl₃ is shut off for 15 minutes while the flows of MTS, NH₃ and N₂ continue to form silicon nitrocarbide. Finally, the flow of all gases except N₂ are halted and the furnace is cooled. Subsequently, a SiC layer is deposited to form a rigidization or wetting layer. The preform may be slurry infiltrated with a SiC-containing slurry followed by melt infiltration with silicon or a silicon alloy to form a SiC/SiC composite.

The microstructure of the functional coatings on the silicon carbide fiber is revealed with transmission electron microscopy (TEM) in conjunction with an electron energy loss spectroscopy (EELS) line scan that shows element profiles. Spikes of nitrogen and silicon with a trace of carbon are observed between the silicon carbide wetting layer and the silicon-doped boron nitride moisture-tolerant layer, revealing the presence of the silicon nitrocarbide (SiNC) barrier layer. A high resolution transmission electron microscopy (TEM) image shown in FIG. 2 reveals a distinctive barrier layer comprising silicon nitrocarbide between the SiC wetting layer and the Si-doped BN moisture tolerant layer. Previous internal development work has demonstrated that a SiNC barrier layer overcoated with a SiC wetting layer of about 0.5 micron in thickness can be effective in protecting the underlying compliant layer/interface multilayer and the silicon carbide fibers.

To clarify the use of and to hereby provide notice to the public, the phrases “at least one of <A>, <B>, . . . and <N>” or “at least one of <A>, <B>, <N>, or combinations thereof” or “<A>, <B>, . . . and/or <N>” are defined by the Applicant in the broadest sense, superseding any other implied definitions hereinbefore or hereinafter unless expressly asserted by the Applicant to the contrary, to mean one or more elements selected from the group comprising A, B, . . . and N. In other words, the phrases mean any combination of one or more of the elements A, B, . . . or N including any one element alone or the one element in combination with one or more of the other elements which may also include, in combination, additional elements not listed. Unless otherwise indicated or the context suggests otherwise, as used herein, “a” or “an” means “at least one” or “one or more.”

While various embodiments have been described, it will be apparent to those of ordinary skill in the art that many more embodiments and implementations are possible. Accordingly, the embodiments described herein are examples, not the only possible embodiments and implementations.

The subject-matter of the disclosure may also relate, among others, to the following aspects:

A first aspect relates to a method of making a ceramic matrix composite that exhibits chemical resistance. The method comprises depositing a compliant layer comprising boron nitride, silicon-doped boron nitride, and/or pyrolytic carbon on silicon carbide fibers, depositing a barrier layer having a high contact angle with molten silicon on the compliant layer, and depositing a wetting layer comprising silicon carbide, boron carbide, and/or pyrolytic carbon on the barrier layer. After depositing the wetting layer, a fiber preform comprising the silicon carbide fibers is infiltrated with a slurry. After slurry infiltration, the fiber preform is infiltrated with a melt comprising silicon, and then the melt is cooled, thereby forming a ceramic matrix composite.

A second aspect relates to the method of the first aspect, wherein the barrier layer comprises silicon nitrocarbide or silicon nitride.

A third aspect relates to the method of the second aspect, wherein the barrier layer comprises amorphous silicon nitrocarbide.

A fourth aspect relates to the method of the second or third aspect, wherein the silicon nitrocarbide includes carbon at a concentration from about 0.3 at. % to 33 at. % and nitrogen at a concentration from about 30 at. % to 60 at. %.

A fifth aspect relates to the method of any preceding aspect, wherein the barrier layer comprises a thickness in a range from about 0.005 micron to about 2 microns.

A sixth aspect relates to the method of the fifth aspect, wherein the thickness of the barrier layer lies in a range from about 0.5 micron to about 2 microns and a thickness of the wetting layer lies in a range from about 0.01 micron to about 0.5 micron, and wherein the barrier layer serves as a rigidization layer.

A seventh aspect relates to the method of the fifth aspect, wherein the thickness of the barrier layer lies in a range from about 0.005 micron to about 0.5 micron and a thickness of the wetting layer lies in a range from 0.5 micron to about 10 microns, and wherein the wetting layer comprises silicon carbide and serves as a rigidization layer.

An eighth aspect relates to the method of any preceding aspect, wherein a thickness of the compliant layer lies in a range from about 0.5 micron to about 3 microns.

A ninth aspect relates to the method of any preceding aspect, wherein the barrier layer has a coefficient of thermal expansion lower than that of the silicon carbide fibers.

A tenth aspect relates to the method of any preceding aspect, wherein depositing the barrier layer on the compliant layer comprises exposing the compliant layer to a gaseous atmosphere comprising: a flow of a carrier gas selected from N₂ and H₂, a flow of silicon-containing gas, and a flow of a nitrogen-containing gas at a temperature in a range from about 700° C. to about 1000° C.

An eleventh aspect relates to the method of the tenth aspect, wherein the silicon-containing gas further comprises carbon.

A twelfth aspect relates to the method of the tenth or eleventh aspect, wherein the silicon-containing gas comprises methyltrichlorosilane (CH₃SiCl₃), and wherein the nitrogen-containing gas comprises ammonia.

A thirteenth aspect relates to the method of any preceding aspect, wherein the compliant layer includes a boron nitride layer, and further comprising depositing a moisture-tolerant layer comprising silicon-doped boron nitride on the boron nitride layer prior to depositing the barrier layer, the boron nitride layer being an interface layer, and the compliant layer thereby comprising a multilayer structure including the moisture-tolerant layer and the interface layer.

A fourteenth aspect relates to the method of the thirteenth aspect, wherein the moisture-tolerant layer includes silicon at a concentration of from about 2 at. % to about 30 at. %.

A fifteenth aspect relates to the method of the thirteenth or fourteenth aspect, wherein a thickness of the moisture-tolerant layer is from about 3 to about 300 times a thickness of the interface layer.

A sixteenth aspect relates to the method of any of the thirteenth through the fifteenth aspects, wherein depositing the interface layer comprises exposing the silicon carbide fibers to a gaseous atmosphere comprising: a flow of a carrier gas selected from N₂ and H₂, a flow of a nitrogen-containing gas, and a flow of a boron-containing gas at a temperature in a range from about 700° C. to about 875° C., and wherein depositing the moisture-tolerant layer comprises introducing a flow of silicon-containing gas into the gaseous atmosphere after depositing the interface layer.

A seventeenth aspect relates to the method of any preceding aspect, wherein the compliant layer comprises a crystalline phase of the boron nitride.

An eighteenth aspect relates to the method of any preceding aspect, wherein the wetting layer comprises a thickness in a range from about 0.1 micron to about 10 microns, or from about 0.2 micron to about 2 microns.

A nineteenth aspect relates to the method of any preceding aspect, further comprising forming the fiber preform prior to coating the silicon carbide fibers with the compliant layer.

An twentieth aspect relates to a fiber preform for fabricating a ceramic matrix composite, the fiber preform comprising: silicon carbide fibers coated with a plurality of functional layers, the functional layers including: a compliant layer comprising boron nitride, silicon-doped boron nitride, and/or pyrolytic carbon deposited on the silicon carbide fibers; a barrier layer having a high contact angle with molten silicon deposited on the compliant layer; and a wetting layer comprising silicon carbide, boron carbide, and/or pyrolytic carbon deposited on the barrier layer.

A twenty-first aspect relates to the fiber preform of the twentieth aspect, wherein the barrier layer comprises silicon nitrocarbide or silicon nitride.

A twenty-second aspect relates to the fiber preform of the twentieth or twenty-first aspect, wherein the silicon nitrocarbide includes carbon at a concentration from about 0.3 at. % to 33 at. % and nitrogen at a concentration from about 30 at. % to 60 at. %.

A twenty-third aspect relates to the fiber preform of any of the twentieth through the twenty-second aspects, wherein the barrier layer comprises amorphous silicon nitrocarbide.

A twenty-fourth aspect relates to the fiber preform of any of the twentieth through the twenty-third aspects, wherein the barrier layer comprises a thickness in a range from about 0.005 micron to about 2 microns.

A twenty-fifth aspect relates to the fiber preform of any of the twentieth through the twenty-fourth aspects, wherein the thickness of the barrier layer lies in a range from about 0.5 micron to about 2 microns and a thickness of the wetting layer lies in a range from 0.01 micron to about 0.5 micron, and wherein the barrier layer serves as a rigidization layer.

A twenty-sixth aspect relates to the fiber preform of any of the twentieth through the twenty-fifth aspects, wherein the thickness of the barrier layer lies in a range from about 0.005 micron to about 0.5 micron and a thickness of the wetting layer lies in a range from 0.5 micron to about 10 microns, and wherein the wetting layer comprises silicon carbide and serves as a rigidization layer.

A twenty-seventh aspect relates to the fiber preform of any of the twentieth through the twenty-sixth aspects, wherein a thickness of the compliant layer lies in a range from about 0.5 micron to about 3 microns.

A twenty-eighth aspect relates to the fiber preform of any of the twentieth through the twenty-seventh aspects, wherein the barrier layer has a coefficient of thermal expansion lower than that of the silicon carbide fibers.

In addition to the features mentioned in each of the independent aspects enumerated above, some examples may show, alone or in combination, the optional features mentioned in the dependent aspects and/or as disclosed in the description above and shown in the figures.

What is claimed is:

1. A method of making a ceramic matrix composite that exhibits chemical resistance, the method comprising:
depositing a compliant layer comprising boron nitride, silicon-doped boron nitride, and/or pyrolytic carbon on silicon carbide fibers;
depositing a barrier layer having a high contact angle with molten silicon on the compliant layer;
depositing a wetting layer comprising silicon carbide, boron carbide, and/or pyrolytic carbon on the barrier layer;
after depositing the wetting layer, infiltrating a fiber preform comprising the silicon carbide fibers with a slurry; and
after infiltration with the slurry, infiltrating the fiber preform with a melt comprising silicon and then cooling the melt, thereby forming a ceramic matrix composite.

2. The method of claim 1, wherein the barrier layer comprises silicon nitrocarbide or silicon nitride.

3. The method of claim 2, wherein the barrier layer comprises amorphous silicon nitrocarbide.

4. The method of claim 2, wherein the silicon nitrocarbide includes carbon at a concentration from about 0.3 at. % to 33 at. % and nitrogen at a concentration from about 30 at. % to 60 at. %.

5. The method of claim 1, wherein the barrier layer comprises a thickness in a range from about 0.005 micron to about 2 microns.

6. The method of claim 5, wherein the thickness of the barrier layer lies in a range from about 0.5 micron to about 2 microns and a thickness of the wetting layer lies in a range from 0.01 micron to about 0.5 micron, and
wherein the barrier layer serves as a rigidization layer.

7. The method of claim 5, wherein the thickness of the barrier layer lies in a range from about 0.005 micron to about 0.5 micron and a thickness of the wetting layer lies in a range from 0.5 micron to about 10 microns, and
wherein the wetting layer comprises silicon carbide and serves as a rigidization layer.

8. The method of claim 1, wherein a thickness of the compliant layer lies in a range from about 0.5 micron to about 3 microns.

9. The method of claim 1, wherein the barrier layer has a coefficient of thermal expansion lower than that of the silicon carbide fibers.

10. The method of claim 1, wherein depositing the barrier layer on the compliant layer comprises exposing the compliant layer to a gaseous atmosphere comprising:
a flow of a carrier gas selected from N₂ and H₂,
a flow of silicon-containing gas, and
a flow of a nitrogen-containing gas
at a temperature in a range from about 700° C. to about 1000° C.

11. The method of claim 10, wherein the silicon-containing gas further comprises carbon.

12. The method of claim 10, wherein the silicon-containing gas comprises methyltrichlorosilane (CH₃SiCl₃), and wherein the nitrogen-containing gas comprises ammonia.

13. The method of claim 1, wherein the compliant layer includes a boron nitride layer, and
further comprising depositing a moisture-tolerant layer comprising silicon-doped boron nitride on the boron nitride layer prior to depositing the barrier layer, the boron nitride layer being an interface layer, the compliant layer thereby comprising a multilayer structure including the moisture-tolerant layer and the interface layer.

14. The method of claim 13, wherein the moisture-tolerant layer includes silicon at a concentration of from about 2 at. % to about 30 at. %.

15. The method of claim 13, wherein a thickness of the moisture-tolerant layer is from about 3 to about 300 times a thickness of the interface layer.

16. The method of claim 13, wherein depositing the interface layer comprises exposing the silicon carbide fibers to a gaseous atmosphere comprising: a flow of a carrier gas selected from N₂ and H₂, a flow of a nitrogen-containing gas, and a flow of a boron-containing gas at a temperature in a range from about 700° C. to about 875° C., and
wherein depositing the moisture-tolerant layer comprises introducing a flow of silicon-containing gas into the gaseous atmosphere after depositing the interface layer.

17. The method of claim 1, wherein the compliant layer comprises a crystalline phase of the boron nitride.

18. The method of claim 1, wherein the wetting layer comprises a thickness in a range from about 0.1 micron to about 10 microns.

19. The method of claim 1, further comprising forming the fiber preform prior to coating the silicon carbide fibers with the compliant layer.

20. A fiber preform for fabricating a ceramic matrix composite, the fiber preform comprising:
silicon carbide fibers coated with a plurality of functional layers, the functional layers including:
a compliant layer comprising boron nitride, silicon-doped boron nitride, and/or pyrolytic carbon deposited on the silicon carbide fibers;
a barrier layer having a high contact angle with molten silicon deposited on the compliant layer; and
a wetting layer comprising silicon carbide, boron carbide, and/or pyrolytic carbon deposited on the barrier layer.
